(19) United States
(12) Patent Application Publication
(10) Pub. No.: US 2009/0305463 A1
(43) Pub. Date: Dec. 10, 2009

(54) System and Method for Thermal Optimized Chip Stacking

(75) Inventors: Gerald K. Bartley, Rochester, MN (US); Darryl J. Becker, Rochester, MN (US); Paul E. Dahlen, Rochester, MN (US); Philip R. Germann, Oronoco, MN (US); Andrew B. Maki, Rochester, MN (US); Mark O. Maxson, Mantorville, MN (US)

Correspondence Address: KING & SPALDING, 1180 PEACHTREE ST., ATLANTA, GA, 30309, US

(73) Assignee: International Business Machines Corporation, Armonk, NY (US)

(21) Appl. No.: 12/134,728

(22) Filed: Jun. 6, 2008

(51) Int. Cl. H01L 21/58

(52) U.S. Cl. 438/109; 257/E21.505

(57) ABSTRACT

A method for thermal optimization comprising the steps of stacking a first chip layer and a second chip layer wherein the second chip layer is rotated in relation to the first chip layer wherein a first hot spot on the first chip layer and a second hot spot on the second chip layer are not spatially aligned; routing a signal input through the first chip layer from a first chip pad on the first chip layer to a first silicon via so as to form a physical input to output twist and a first signal output; and routing the first signal output from the first chip layer through a second chip layer from a second chip pad on the second chip layer to a second silicon via so as to form a second signal output.

### BACKGROUND OF THE INVENTION

1. Field of the Invention

The present invention relates to a system and method for stacking integrated circuits or chips. Specifically, the present invention relates to a system and method for thermal optimization in stacked chips.

2. Description of Background

Integrated circuit or chip manufacturers use chip stacks in order to build more powerful devices. For example, packaged integrated circuit devices, i.e., chips, including, for example, microprocessors, memory devices are stacked together, e.g., back-to-front or back-to-back. Chip stacks are beneficial because they allow more compact circuit arrangements and, therefore, more efficient use of space, e.g., on circuit boards. The advent of thru-silicon via on three-dimensional chip-stacking as a packaging approach has opened up opportunities for creating more compact functions than ever before. Stacks of chips have been demonstrated with greater than ten chips in the stack.

Those with ordinary skill in the art will recognize the electrical advantages of chip stacking. One challenge of stacking chips is thermal management. When the stack of chips is in use, the chips will generate heat. Specifically, chip stacks with a greater number of chips create problems with cooling. Because the chip stacks contain multiple chips, the stacks generate more heat per unit volume. If such heat is not dissipated out of the chip stack, technical issues may occur. In most package approaches, heat will be extracted out of the top of the stack and/or out of the bottom of the stack, usually to a lesser degree. Getting the “heat” out of the die in the middle of the stack is generally recognized as a large challenge.

Further complicating this challenge is the fact that most functions implemented in silicon do not have a uniform power dissipation density. Hence, hot spots are formed where the activity of a macro, e.g., a processor, is significantly higher than other areas of the chip, e.g., a memory array or random logic. Hot spots may form where a segment of the silicon is, for example, 10, 15, or even 20 degrees Celsius, hotter than the surrounding areas.

Stacking multiple chips of the same type will increase the hot spot effect in a 3-dimensional manner. Specifically, if multiple die are stacked on-top of each other, the individual silicon layers may have their hot spots aligned directly above and below each other. This may create additional heating effects and cause the hot spots to be even more pronounced relative to the rest of the silicon surface area in the stack.

One solution is to rotate the die in a stack by wire-bond. This is generally done for memory devices has a much more uniform power dissipation density than that of logic or analog functions. However, wire bonding is not practical to allow the rotation of the bus interface along with the die rotation and is not very effective in large chip stacks because the bonds get long, degrading signal and power integrity.

### SUMMARY OF THE INVENTION

A method for thermal optimization comprising the steps of stacking a first chip layer and a second chip layer wherein the second chip layer is rotated in relation to the first chip layer wherein a first hot spot on the first chip layer and a second hot spot on the second chip layer are not spatially aligned; routing a signal input through the first chip layer from a first chip pad on the first chip layer to a first silicon via so as to form a physical input to output twist and a first signal output; and routing the first signal output from the first chip layer through a second chip layer from a second chip pad on the second chip layer to a second silicon via so as to form a second signal output.

The present invention is generally directed at providing a low cost solution for dissipating heat generated within chip stacks.

The approach disclosed here is a rotation of the die in concert with thru-silicon via and stacks of flip-chip devices with non-uniform power dissipation.

Using the flexibility of thru-silicon via technology, a method for creating a more uniform power density by distributing the hot spots of an individual layer in a chip stack is created. This reduces the impact of the hot spots on adjacent layers within the stack, and thus reduces the magnitude between the average temperature on the die and the hot spots.

The present invention is advantageous over previous solutions because the chips used on each of the layers may be identical, therefore creating no additional production costs.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates a side view of an exemplary chip stack.

FIG. 2 illustrates a perspective view of a chip in accordance with the present invention.

FIG. 3 illustrates an exemplary wire routing in accordance with the present invention.

FIG. 4 illustrates a perspective view of a chip stack in accordance with the present invention.

The detailed description explains the preferred embodiments of the invention, together with advantages and features, by way of example with reference to the drawings.

### DETAILED DESCRIPTION OF THE INVENTION

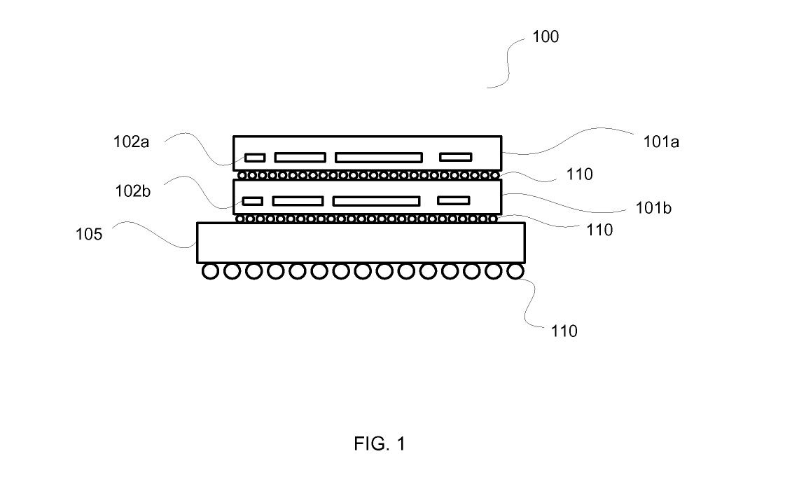

FIG. 1 illustrates a side view of an exemplary chip stack 100. Chip stack 100 includes chips 101a and 101b, package 105, and C4 connectors 110. In this exemplary figure, chips 101a and 101b sit directly above and below each other. Each of the processor cores in respective chips 101a and 101b create hot spots 102a and 102b that also sit directly above and below each other. These hotter areas, hot spots 102a and 102b, may heat each other causing an even greater temperature increase over the average in this region.

Those of ordinary skill in the art will recognize that chip stack 100 may include more than the exemplified two chips. In addition, it will be understood that each of the chips include other components such as memory 103a and 103b, memory controls 104a and 104b, and other logic components. Furthermore, it will be understood that hot spots 102a and 102b may be created by elements in the chip other than the processor cores.

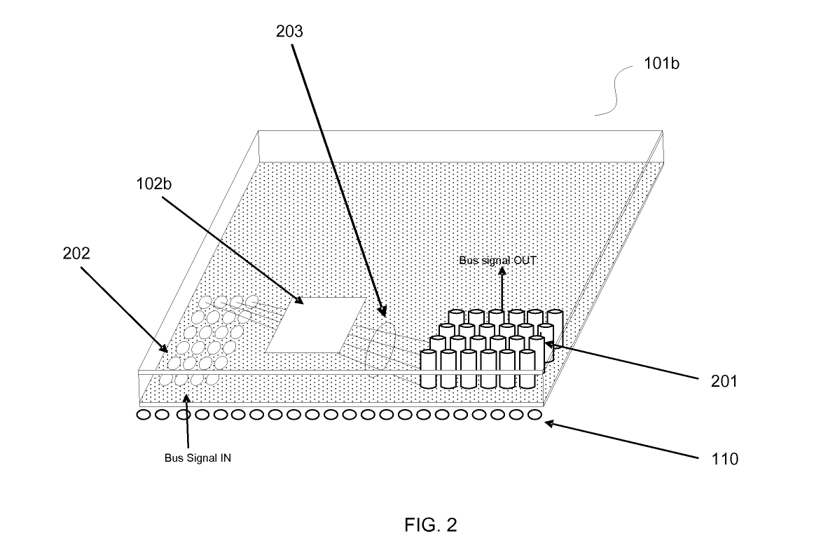

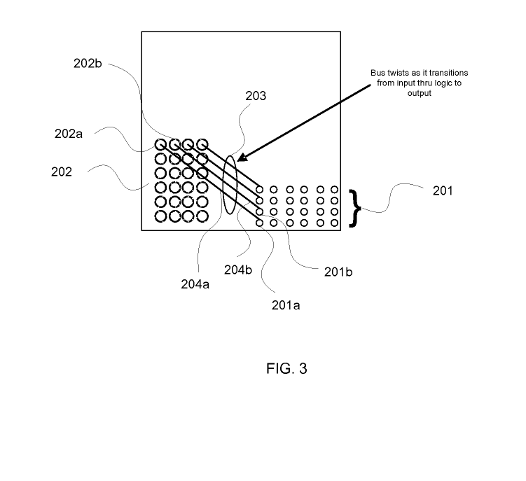

FIG. 2 illustrates a perspective view of chip 101b included in chip stack 100. As described above, chip 101b may include various elements such as a processor core, memory (not shown), memory control (not shown), and other logic components. Chip 101b connects to other layers, e.g., other chips or the package, of the chip stack with C4 connectors 1 10. Chip 101b also includes silicon vias 201, chip pad 202, and bus router 203. As further described above, elements within chip 101b may create hot spot 102b. In accordance with a preferred embodiment of the present invention, the wiring necessary to connect chip 101b to other chips, e.g., chip 101a, may be routed from chip pad 202 to silicon vias 201 via bus router 203. Therefore, the bus signal enters chip 101b through chip pad 202 and is routed in wires 204 through bus router 203 and sent out through silicon vias 201. Wires 204 are twisted as they transition from input through logic to output. FIG. 3 illustrates an exemplary embodiment of the physical “twists” of wires 204 from input to output. For example, wire 204a is routed from chip pad connector 202a to silicon via 201a. Similarly, wire 204b is routed from chip pad connector 202b to silicon via 201b, and so on.

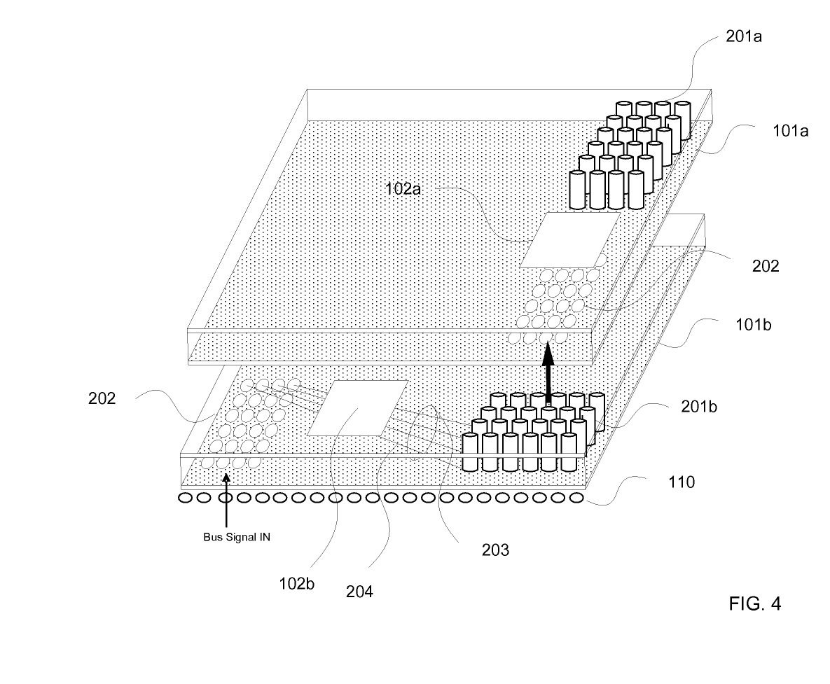

FIG. 4 illustrates a perspective view of stacked chips 101a and 101b. The elements of chip 101b are identical as those described with reference to FIG. 2. Chip 101a also includes similar elements although not all are shown in FIG. 4. Specifically, chip 101a includes silicon via 201a, hot spot 102a, chip pad 202, wires (not shown), and a bus router (not shown). In accordance with the present invention, chip 101a is rotated 90 degrees in relation to chip 101b such that the output from chip 101b from silicon via 201b is the input to chip pad 202 in chip 101a. As described with respect to FIG. 3, wires 204 are physically “twisted” when routed from the input to the output. This may be done within each of the layers of the chip stack.

Each chip layer added to the chip stack is rotated such that the hot spots are not lying directly above and below each other or otherwise spatially aligned. For example, as shown in FIG. 4, chip 101a is rotated 90 degrees in relation to chip 101b. Because the chips are rotated in order to optimize the thermal energy in each chip and avoid layering of hot spots, the design of the chip does not need to change from layer to layer. More specifically, the same chip design can be used for each of the layers, e.g., 101a and 101b can be identical chips. One of ordinary skill in the art will appreciate that the rotation of the chips does not need to be 90 degrees, but may be other placements such as 180 degrees or 270 degrees. In addition, those of ordinary skill in the art will appreciate that the chip designs do not need to be the same for each of the layers, but having one chip design will be cost efficient. Additionally, the chip stack is not limited to the number of chip layers shown in FIG. 4.

In a preferred embodiment, the standard metal layer may be used to route the bus from the signal inside to the signal outside. This embodiment keeps the routing internal to the chip wiring layer, e.g., on the same layer as the C4 connectors and on the bottom of the chip. In another preferred embodiment of the present invention, a new layer of metal may be added to route wires through the bus router. In this embodiment, the routing is performed on the back side of the chip.

The diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

1. A method for thermal optimization comprising the steps of:
stacking a first chip layer and a second chip layer wherein the second chip layer is rotated in relation to the first chip layer wherein a first hot spot on the first chip layer and a second hot spot on the second chip layer are not spatially aligned;
routing a plurality of signal inputs along a plurality of wires through the first chip layer from a first chip pad on the first chip layer to a first plurality of silicon vias so as to form a physical input to output twist and a first plurality of signal outputs; and
routing the first plurality of signal outputs from the first chip layer through the second chip layer from a second chip pad on the second chip layer to a second plurality of silicon vias so as to form a second plurality of signal outputs,
wherein the physical input to output twist comprises a physical twist of the plurality of wires from the first chip pad to the first plurality of silicon vias.
